(19) United States
(12) Patent Application Publication
(10) Pub. No.: US 2009/0009220 A1
(43) Pub. Date: Jan. 8, 2009

(54) Signal generating apparatus, periodic-signal observing system, integrated circuit, periodic-signal observing method, and method of testing integrated circuit

(75) Inventor: Sadanori Akiya, Kawasaki (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 12/216,419

(22) Filed: Jul. 3, 2008

Related U.S. Application Data
(63) Continuation of application No. PCT/JP2006/302223, filed on Feb. 6, 2006.

(51) Int. Cl. G01R 31/26; H03B 19/00; G01P 3/48

(52) U.S. Cl. 327/117; 324/765; 324/166

(57) ABSTRACT

A signal generating apparatus having an LSI circuit in which a plurality of cycle-observing signals are generated to be output via an I/O circuit to a device outside the LSI circuit in order to observe a prescribed periodic signal in the LSI circuit. The apparatus includes: a frequency-dividing circuit that frequency-divides the periodic signal at a preset frequency division ratio; and a delay circuit that imparts a prescribed phase difference to the signal to be frequency-divided by the frequency-dividing circuit, thereby obtaining a plurality of signals that differ in phase from one another.

### TECHNICAL FIELD

This application is a continuation of International Application No. PCT/JP2006302223, filed Feb. 9, 2006, the disclosure of which is herein incorporated in its entirety by reference. The present invention relates to a technique of observing the cycle of a periodic signal.

### BACKGROUND ART

In recent years, semiconductor integrated circuits (hereinafter referred to as is LSIs), such as CPUs incorporated in servers and personal computers, have their operating frequency (clock frequency) prominently increased. In order to guarantee and verify the operation of LSIs and to analyze any malfunction in the LSIs, the LSI internal signals (e.g., synchronous clock signal) must be observed from outside the LSIs. Therefore, there is a demand for a technique of observing the cycle and the like of the high-frequency signals used in the LSIs.

FIG. 11 and FIG. 12 are diagrams that explain conventional methods of observing a high-frequency signal.

In the conventional method shown in FIG. 11, a high-frequency signal in the LSI is directly output to the outside to observe the cycle and the like. In such a observing method, an I/O circuit is used as interface for outputting the high-frequency signal from the LSI.

On the other hand, in the conventional method shown in FIG. 12, a frequency-dividing circuit divides the high-frequency signal, thereby converting the same to a low-frequency signal in the LSI. The low-frequency signal is output from the LSI. The cycle and the like of the low-frequency signal are then observed. In this case, too, an I/O circuit is used as interface for interaction between the inside and outside of the LSI. FIG. 13 shows the circuit configuration of the frequency-dividing circuit used in the observing method illustrated in FIG. 12. The frequency-dividing circuit shown in FIG. 13 outputs a signal having a quarter of the frequency of the input waveform.

### DISCLOSURE OF THE INVENTION

### Problems to be Solved by the Invention

In the case of the conventional observing method shown in FIG. 11, the I/O circuit used as interface for interaction between the inside and outside of the LSI needs to operate at high speed in order to output high-frequency signals. The operating frequency of LSIs has remarkably increased in recent years. It has therefore become difficult, from a technical point of view, to develop such an I/O circuit that can transmit such a high-frequency signal from an LSI. If an I/O circuit that operates at low speed is used as interface, a problem will arise. That is, any signal to be output from the LSI will have an unstable waveform or will not be output at all.

In the case of the another conventional observing method shown in FIG. 12, only the waveform of the signal obtained by the frequency dividing can be observed. That is, the cycle of the original high-frequency signal cannot be observed at high precision.

The present invention has been made in order to solve the problems described above. An object of the invention is to provide a technique of observing a predetermined periodic signal in an LSI circuit, at low cost and at high precision.

### Means for Solving the Problems

To solve the problems set forth above, a signal generating apparatus according to the present invention has an LSI circuit in which a plurality of cycle-observing signals are generated to be output via an I/O circuit to a device outside the LSI circuit in order to observe a prescribed periodic signal in the LSI circuit. The signal generating apparatus includes: a frequency-dividing circuit that frequency-divides the periodic signal at a preset frequency division ratio; and a delay circuit that imparts a predetermined phase difference to the signal to be frequency-divided by the frequency-dividing circuit, thereby obtaining a plurality of signals that differ in phase from one another.

In the signal generating apparatus according to this invention, the delay circuit may impart a prescribed phase difference to the periodic signal to be frequency-divided by the frequency-dividing circuit, before a frequency-dividing process is performed, thereby obtaining a plurality of signals that differ in phase from one another, and the frequency-dividing circuit may frequency-divide the plurality of signals obtained in the delay circuit and being different in phase, each at a preset frequency division ratio.

In the signal generating apparatus according to this invention, the delay circuit may impart a prescribed phase difference to the signal frequency-divided by the frequency-dividing circuit, thereby obtaining a plurality of signals that differ in phase from one another.

In the signal generating apparatus according to the invention, the delay circuit may impart a phase difference to the signal to be frequency-divided by the frequency-dividing circuit. This phase difference corresponds to the time between a timing at which the periodic signal undergoes a certain waveform change and a timing at which the periodic signal undergoes the next waveform change.

In the signal generating apparatus according to the invention, the frequency-dividing circuit frequency-divides the periodic signal at a frequency division ratio that enables the I/O circuit to transmit the periodic signal.

A periodic-signal observing system according to the present invention is designed to observe a periodic signal in an LSI circuit by guiding the periodic signal out of the LSI circuit via an I/O circuit. The system includes a signal generating apparatus of such a type as described above; and a cycle-observing unit that observes the cycle of the periodic signal based on a phase difference between a plurality of signals generated by the signal generating apparatus and used to observe the cycle of the periodic signal.

An integrated circuit according to the present invention is designed to perform a prescribed process based on a reference signal that is a periodic signal. The integrate circuit includes: a reference-signal generating unit that generates the reference signal in the integrated circuit; a frequency-dividing circuit that frequency-divides the reference signal at a preset frequency division ratio; a delay circuit that imparts a prescribed phase difference to the signal to be frequency-divided by the frequency-dividing circuit, thereby obtaining a plurality of signals that differ in phase from one another; and an I/O circuit that guides, from the integrated circuit, a plurality of signals that have been frequency-divided by the frequency-dividing circuit and imparted with the prescribed phase difference by the delay circuit.

In the integrated circuit according to this invention, the delay circuit may impart the prescribed phase difference to the reference signal to be frequency-divided by the frequency-dividing circuit, before a frequency-dividing process is performed, thereby obtaining a plurality of signals that differ in phase from one another, and the frequency-dividing circuit may frequency-divide the plurality of signals obtained in the delay circuit and being different in phase, each at a preset frequency division ratio.

In the integrated circuit according to the invention, the delay circuit may impart a prescribed phase difference to the signal frequency-divided by the frequency-dividing circuit, thereby obtaining a plurality of signals that differ in phase from one another.

In the integrated circuit according to the invention, the delay circuit may impart a phase difference to the signal to be frequency-divided by the frequency-dividing circuit, the phase difference corresponding to the time between a timing at which the reference signal undergoes a certain waveform change and a timing at which the reference signal undergoes the next waveform change.

In the integrated circuit according to this invention, the frequency-dividing circuit may frequency-divide the periodic signal at a frequency division ratio that enables the I/O circuit to transmit the periodic signal.

In a periodic-signal observing method according to the present invention, a periodic signal is guided from an LSI circuit via an I/O circuit and then observed. The method includes: a frequency-dividing step that frequency-divides a prescribed periodic signal in the LSI circuit, at a preset frequency division ratio; a delaying step that imparts a prescribed phase difference to the signal to be frequency-divided in the frequency-dividing step, thereby obtaining a plurality of signals that differ in phase from one another; and a cycle-observing step that observes the cycle of the periodic signal based on a phase difference between a plurality of signals for cycle observation generated in the frequency-dividing step and the delaying step.

In the periodic-signal observing method according to this invention, the delaying step imparts the prescribed phase difference to the periodic signal to be frequency-divided in the frequency-dividing step, before a frequency-dividing process is performed, thereby obtaining a plurality of signals that differ in phase from one another, and the frequency-dividing step frequency-divides the plurality of signals obtained in the delay step and being different in phase, each at a preset frequency division ratio.

In the periodic-signal observing method according to the invention, the delaying step imparts a prescribed phase difference to the periodic signal frequency-divided in the frequency-dividing step, thereby obtaining a plurality of signals that differ in phase from one another.

In the periodic-signal observing method according to the invention, the delaying step imparts a phase difference to the signal to be frequency-divided in the frequency-dividing step. This phase difference corresponds to the time between the timing at which the periodic signal undergoes a certain waveform change and the timing at which the periodic signal undergoes the next waveform change. In the periodic-signal observing method according to the invention, the frequency-dividing step frequency-divides the periodic signal at a frequency division ratio that enables the I/O circuit to transmit the periodic signal.

A method of testing an integrated circuit, according to the present invention, includes: a first step that frequency-divides a first periodic signal for driving the integrated circuit, at a preset frequency division ratio, and imparts a prescribed phase to the first periodic signal, thereby generating a second periodic signal; a second step that frequency-divides the first periodic signal, at the preset frequency division ratio, and imparts a prescribed phase difference to the second periodic signal, thereby generating a third periodic signal; a fourth step that outputs the second periodic signal and the third signal from the integrated circuit; and a fifth step that determines a phase difference between the second and third periodic signals output in the fourth step.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagram explaining the basic configuration of a periodic-signal observing system according to the embodiment;

FIG. 2 is a timing chart representing the relation between the signals (high-frequency signal A, low-frequency signal B and low-frequency signal C) shown in FIG. 1;

FIG. 3 is a diagram showing an example of the internal circuit configuration of an LSI 9 that has a signal generating apparatus 1 according to the embodiment;

FIG. 4 is a diagram showing an example of the circuit configuration of the frequency-division delay circuit 101 and the frequency-division delay circuit 102, both shown in FIG. 3;

FIG. 5 is a diagram showing an example of the circuit configuration of the synchronizing circuit 103 used in this embodiment;

FIG. 6 is a timing chart explaining the signals generated in the signal generating apparatus 1;

FIG. 7 is a timing chart explaining the signals generated in the signal generating apparatus 1;

FIG. 8 is a timing chart explaining the signals generated in the signal generating apparatus 1;

FIG. 9 is a flowchart explaining a sequence of major steps of a method of observing a periodic signal, according to this embodiment;

FIG. 10 is a flowchart explaining a sequence of major steps of a method of observing a periodic signal, according to this embodiment;

FIG. 11 is a diagram explaining a conventional method of observing a high-frequency signal;

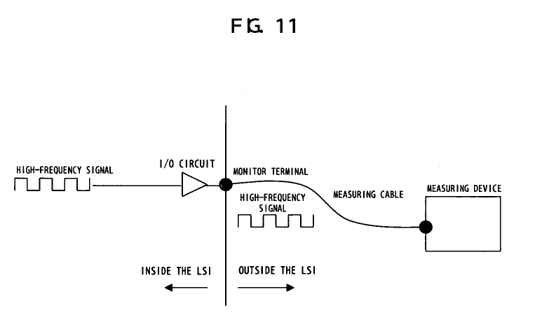

FIG. 12 is a diagram explaining another conventional method of observing a high-frequency signal; and

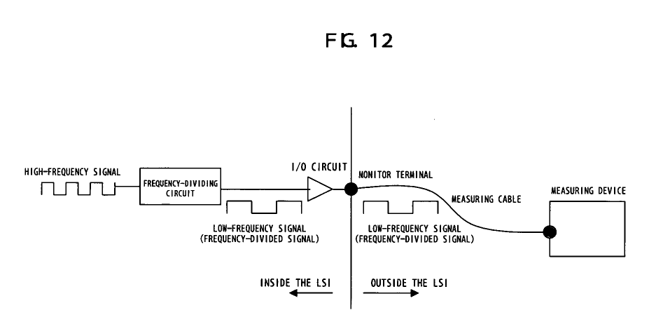

FIG. 13 is a diagram showing an example of the circuit configuration of the frequency-dividing circuit used in the observing method shown in FIG. 12.

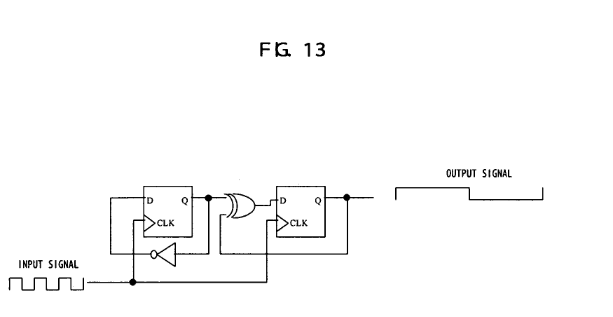

### BEST MODE FOR CARRYING OUT THE INVENTION

Now, preferred embodiments of the present invention will be described by referring to the accompanying drawings.

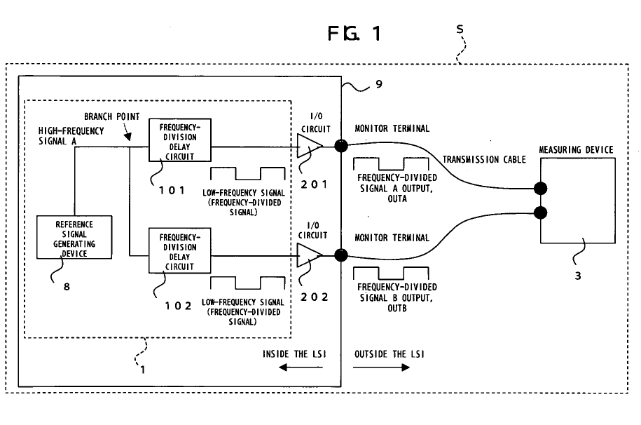

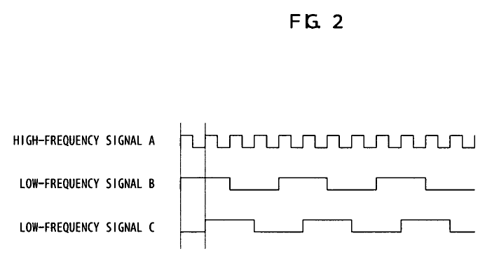

FIG. 1 is a diagram explaining the basic configuration of a periodic-signal observing system according to this embodiment. FIG. 2 is a timing chart representing the relation between the signals (high-frequency signal A, low-frequency signal B and low-frequency signal C) shown in FIG. 1.

The periodic-signal observing system S according to the present embodiment includes an LSI circuit (equivalent to an integrated circuit) 9 and a measuring device (cycle-observing unit) 3. The LSI circuit 9 includes a signal generating apparatus 1, an I/O circuit 201, and an I/O circuit 202. The signal generating apparatus 1 generates a plurality of signals for cycle observation to be output to the outside of the LSI circuit 9 through the I/O circuits in the LSI circuit 9 in order to observe the high-frequency signal A (reference signal that is a prescribed periodic signal (equivalent to the first periodic signal)) generated in a reference-signal generating device 8 in the LSI 9. (These signals are frequency-divided signal outputs A and B shown in FIG. 1, which correspond to a second periodic signal and a third periodic signal, respectively.) The measuring device 3 measures the periodic signals based on the phase difference between the plurality of signals for cycle observation generated by the signal generating apparatus 1. The I/O circuits 201 and 202 are interfaces that transmit the signals generated in the signal generating apparatus 1, to the measuring device 3. In the LSI circuit 9, prescribed processes are performed in accordance with a reference signal generated by the reference-signal generating device 8.

More specifically, the signal generating apparatus 1 includes a frequency-division delay circuit 101 and a frequency-division delay circuit 102. Each of the frequency-division delay circuit 101 and frequency-division delay circuit 102 has a frequency-dividing circuit that frequency-divides the high-frequency signal A with a preset frequency division ratio. The frequency-division delay circuit 101 and frequency-division delay circuit 102 cooperate with each other, imparting a prescribed phase difference to the signals that they have frequency-divided. That is, the frequency-division delay circuits 101 and 102 function as delay circuits for generating a plurality of signals that differ in phase from one another.

The measuring device 3 has a plurality of input channels. It is constituted by a measuring device (e.g., oscilloscope) that can observe the phase difference between a plurality of periodic signals. As shown in FIG. 1, the two signals (frequency-divided signals) generated by the signal generating apparatus 1 are transmitted to the measuring device 3 via the I/O circuit 201 and I/O circuit 202, respectively.

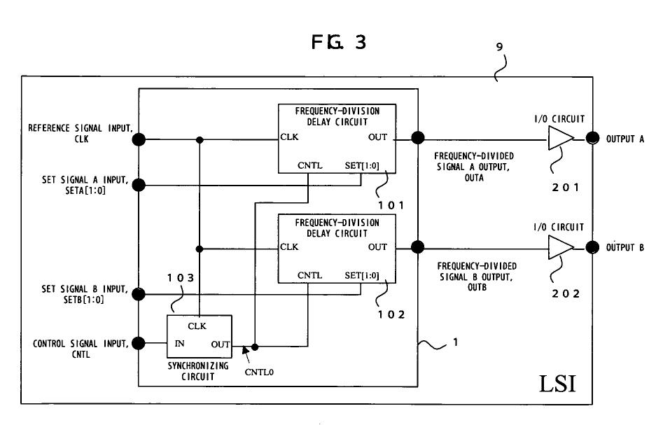

FIG. 3 is a diagram showing an example of the internal circuit configuration of the LSI 9 that has the signal generating apparatus 1 according to the present embodiment. As shown in this figure, the signal generating apparatus 1 includes two frequency-division delay circuits 101 and 102 and a synchronizing circuit 103. The frequency-division delay circuits 101 and 102 receive a reference signal and output frequency-divided signals. The synchronizing circuit 103 synchronizes the control signals that control these frequency-division delay circuits.

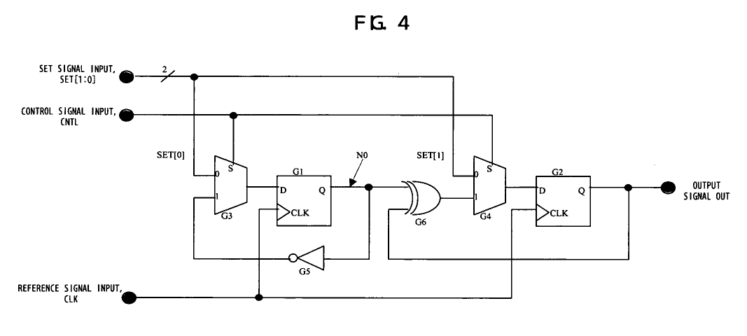

FIG. 4 shows examples of the circuit configuration of the frequency-division delay circuit 101 and the frequency-division delay circuit 102, both shown in FIG. 3. (Here, the frequency division ratio is set to 4.) In FIG. 4, G1 and G2 denote circuits called D-type flip-flops (hereinafter referred to as FF), each of which latches the value of an input data signal D at the leading edge of the reference clock signal CLK (namely, the timing at which the signal waveform changes from L to H) and then transfers the input data signal D, as output signal Q, to the next-state component. G3 and G4 denote selector circuits that switch the output signals in accordance with the value of a select signal S. G5 is an inverter that inverts the input signal and then outputs the signal. G6 is an XOR circuit that outputs the exclusive OR of the input signals. Note that the frequency division ratios applied to the frequency-division delay circuit 101 and frequency-division delay circuit 102 are set to such values that the I/O circuit 201 and I/O circuit 202 can output periodic signals from the LSI 9.

The high-frequency signal to be observed is thus frequency-divided in accordance with the performance of the I/O circuits that serve as interfaces between the LSI and the device provided outside the LSI. Hence, periodic signals can be observed at high precision even if the I/O circuits used cannot cope with the high-frequency signal. In other words, no I/O circuits specially designed to cope with the high-frequency signal to be observed need to be provided. This helps to reduce the manufacturing cost of the periodic-signal observing system.

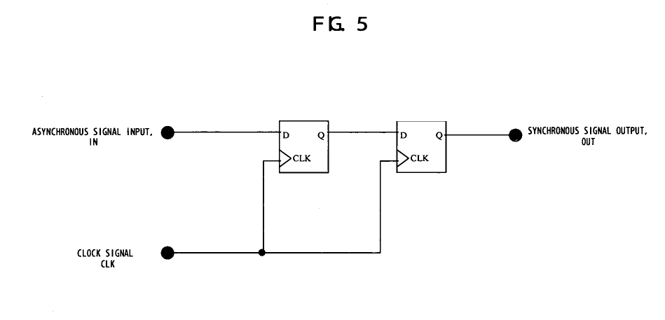

The synchronizing circuit 103 shown in FIG. 3 is a circuit designed to prevent the output of any FF from assuming a meta-stable state (i.e., the output staying at a intermediate potential between H level and L level) when an asynchronous signal is input to the FF. FIG. 5 is a diagram showing an example of the circuit configuration of the synchronizing circuit 103 used in the present embodiment. The synchronizing circuit 103 of this example is constituted by connecting a plurality of FFs in different stages in series.

The operation of the signal generating apparatus 1 according to this embodiment will be explained.

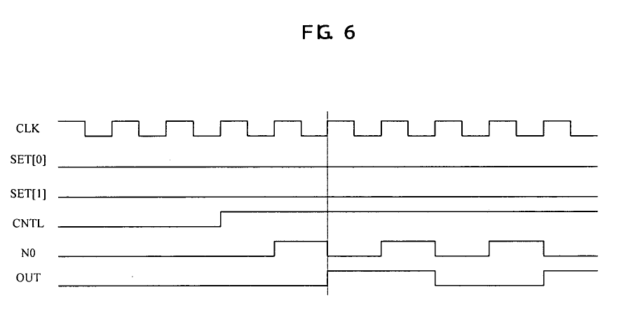

First, it will be explained how the frequency-division delay circuits of the configuration shown in FIG. 4 operate when the set signal SET[0]=L and the set signal SET[1]=L. FIG. 6 is a timing chart explaining the signals that the frequency-division delay circuits generate in this case.

To make the frequency-division delay circuits start operating, control signals CNTL is set to L (CNTL=L). While CNTL remains at L, G3 and G4 select and output the “0” input. Therefore, N0=L and OUT=L. When CNTL becomes H (CNTL=H) at a certain timing, G3 and G4 select and output the “1” input. As a result, N0 changes to H (N0=H) at the leading edge of the next reference signal CLK. Thereafter, G3 and G4 keep operating, inverting the value at every leading edge of the reference signal CLK. G2 operates, inverting the value at the leading edge of the reference signal CLK when N0 is H (N0=H).

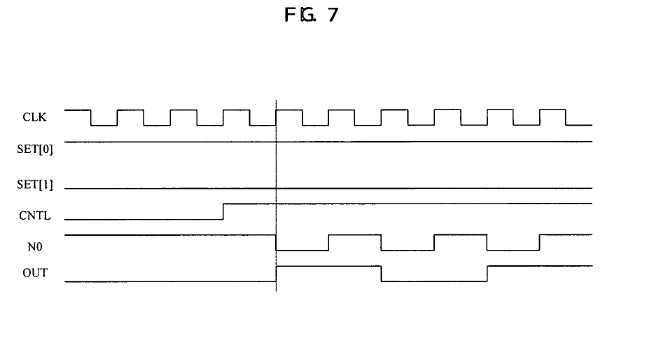

It will be explained how the frequency-division delay circuits of the configuration shown in FIG. 4 operate when the set signal SET[0]=H and the set signal SET[1]=L. FIG. 7 is a timing chart explaining the signals that the frequency-division delay circuits generate in this case.

While CNTL remains L (CNTL=L), G3 and G4 select the “0” input and outputs the same. Therefore, N0=H and OUT=L. When CNTL changes to H (CNTL=H), G3 and G4 select the “1” input and outputs the same. N0 changes to L (N0=L) at the leading edge of the next reference signal CLK. Thereafter, G3 and G4 keeps operating, inverting the value at every leading edge of the reference signal CLK. G2 operates, inverting the value at the leading edge of the reference signal CLK as long as N0=H.

As the comparison of FIGS. 6 and 7 reveals, due to the value of SET[1:0], a signal OUT generated by dividing the frequency of the input signal by 4 is output at the leading edge of the reference signal CLK.

Here, the apparatus is configured to impart a phase difference to the high-frequency signal that should be frequency-divided by the frequency-dividing circuit. This phase difference corresponds to the time between the timing when the waveform of the periodic signal changes from L to H (i.e., timing when a prescribed waveform change occurs) and the timing when the waveform of the periodic signal rises next. The phase difference imparted is not limited to this, nevertheless. A phase difference corresponding to the time between the timing when the waveform of the periodic signal changes from H to L and the timing when the waveform of the periodic signal falls next may be imparted.

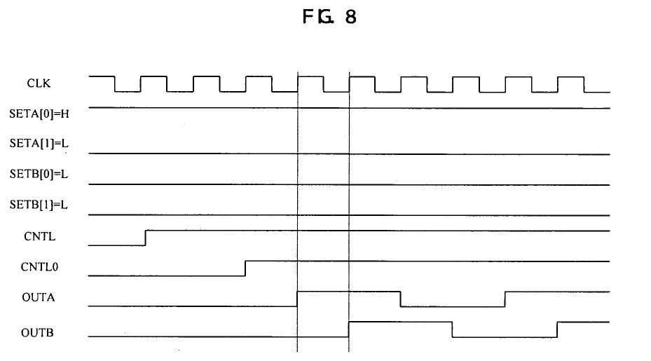

How the circuit shown in FIG. 3 operates when the set signal A is set to SETA[0]=H, SETA[1]=L, SETB[0]=L or SETB[1]=L. FIG. 8 is a timing chart explaining the signals the signal generating apparatus 1 generates in this case.

While the control signal CNTL remains 0 (CNTL=0), the FFs provided in the frequency-division delay circuit 101 and the frequency-division delay circuit 102 hold the set signal SETA and SETB, respectively, which they have acquired. If the control signal CNTL changes to H (CNTL=H), CNTL0 will become H (CNTL0=H) upon lapse of cycles during which the signal passes the synchronizing circuit. The frequency-division delay circuits 101 and 102 therefore start operating at the same time (in the first and second steps). The frequency-division delay circuits 101 and 102 operate in such a way as described above. They generate two signals OUTA and OUTB, each having a frequency that is a quarter of that of the reference signal CLK (in the third step). The phases of these two signals deviate from that of the reference signal CLK by one cycle.

Hence, the cycle of the reference signal CLK can be observed by outputting the periodic signals generated by the signal generating apparatus 1 from the LSI as shown in FIG. 1 and by observing the phase difference between the periodic signals (in the fourth step). Thus, a method of testing the integrated circuit according to this embodiment includes: a first step that frequency-divides a first periodic signal used to drive the integrated circuit, with a preset frequency division ratio, and imparts a prescribed phase to the first periodic signal, thereby generating a second periodic signal; a second step that frequency-divides the first periodic signal with a preset frequency division ratio and imparts a specified phase difference to the second periodic signal, thereby generating a third periodic signal; a thirds step that outputs the second periodic signal and the third periodic signal from the integrated circuit; and a fourth step that determines the phase difference between the second and third periodic signals output in the third step.

In a similar sequence, the set signals SETA and SETB for the frequency-division delay circuits 101 and 102 can be set to any values, and the second and third cycles of the reference signal CLK can then be observed.

In order to observe the cycle of reference signal CLK accurately from the phase difference between the waveforms observed, the delay times in two paths from the branch point to the measuring device should be equal to each other. In practice, however, these delay times inevitably differ from each other, because the circuit performance differs from the design performance or the transmission cable is shorter or longer than the design value. This delay-time error can be corrected, nonetheless, because it can be observed as a waveform-phase difference between the signals the signal generating apparatus 1 generates if the signals SETA and SETB are set to the same value.

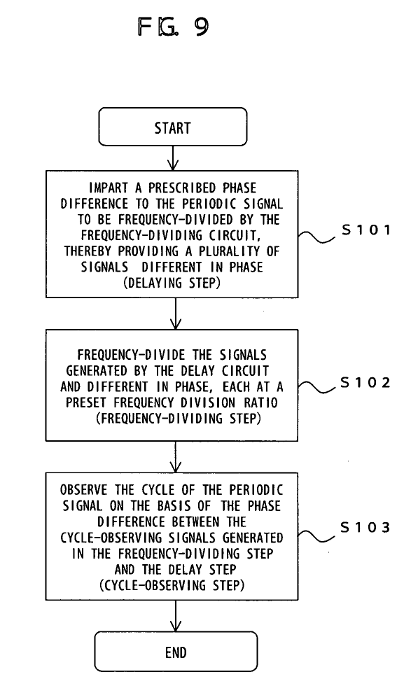

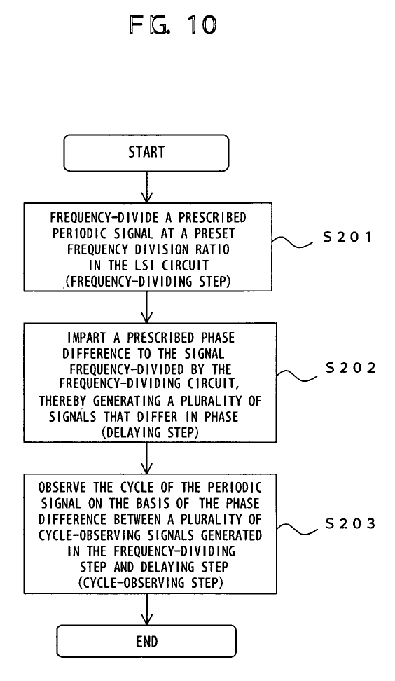

FIG. 9 and FIG. 10 are flowcharts explaining a sequence of major steps of a method of observing a periodic signal, according to this embodiment. In the embodiment, as described above, the frequency-division delay circuits 101 and 102 generate a plurality of signals from the reference signal CLK. If the process of dividing the frequency of the reference signal CLK and the process of generating signals that differ in phase are performed at different times, it does not matter which process is performed first. That is, it suffices to generate a plurality of signals (cycle-observing signals) from the reference signal CLK in the signal generating apparatus according to this embodiment.

FIG. 9 is a flowchart explaining the sequence of performing frequency division on the respective signals generated from the reference signal CLK and being different in phase from one another.

At first, a prescribed phase difference is imparted to the periodic signal (i.e., reference signal CLK) that should be frequency-divided by the frequency-dividing circuit, providing a plurality of signals that differ in phase from one another (delaying step) (S101).

Next, the signals generated in the delay step and different in phase from one another are frequency-divided, each at a preset frequency division ratio. A plurality of signals to be observed in terms of cycle are thereby generated (frequency-dividing step) (S102).

The measuring device 3 measures the cycle of the periodic signal from the phase difference between the signals generated in the frequency-dividing step and the delay step (cycle-observing step) (S103).

FIG. 10 is a flowchart explaining a sequence of major steps of a process of generating a plurality of signals different in phase, from the periodic signals obtained by means of the frequency division.

At first, the reference signal CLK is frequency-divided at a preset frequency division ratio in the LSI circuit 9 (frequency-dividing step) (S201).

Next, a prescribed phase difference is imparted to the signal generated in the frequency-dividing step, thereby generating a plurality of periodic signals that differ in phase from one another (delaying step) (S202). Here, the phase difference imparted to the signal generated in the frequency-dividing step corresponds to the time between the timing at which the reference signal CLK undergoes a certain waveform change (e.g., the leading or trailing edge of the waveform) and the timing at which the reference signal undergoes the next waveform change.

The measuring device 3 measures the cycle of the periodic signal from the phase difference between a plurality of signals which has been generated in the frequency-dividing step and delaying step and which are used to observe the cycle of the periodic signal (cycle-observing step) (S203).

In the present embodiment, two frequency-division delay circuits are provided (thus, two cycle-observing signals are generated). The configuration is not limited to this, nevertheless. More frequency-division delay circuits can be arranged parallel to one another.

If two frequency-division delay circuits output signals, each having a frequency that is a quarter of that of the reference signal, only one of the four consecutive cycles of the reference signal CLK can be observed. If more frequency-division delay circuits, for example four circuits, are arranged parallel to one another, and output four signals each having a quarter of the frequency of the reference signal, the four consecutive cycles of the reference signal can be all observed. The reference signal CLK generated by an ordinary PLL (Phase Locked Loop) circuit is thereby output from a circuit in which each of four frequency-division delay circuits outputs a signal having a quarter of the frequency of the reference signal. Then, a cycle-to-cycle jitter can be observed from the relation (difference) between the consecutive cycles (between any cycle and the next cycle), thus accomplishing one of the functions any PLL circuit should perform.

Thus, in this embodiment, frequency-division delay circuits are used, lowering the signal frequency and rendering it easy to output and observe a waveform, and the phase difference between two waveforms is observed, thereby observing the cycle of the reference signal. That is, this embodiment can easily observe the cycle of a high-frequency signal that is hardly observed in conventional method.

Moreover, the edge intervals of the waveform (i.e., time between the leading or trailing edges of waves) of the reference signal that serves as an output trigger in each frequency-division delay circuit can be varied (that is, the phase difference between signals is variable). Therefore, it is possible to obverse not only one cycle, but also a plurality of cycles (two cycles, three cycles, and so on). Further, if the edges used as triggers are the same, the error of delaying the measuring path can be measured. The errors resulting from the observation path can therefore be corrected.

The present invention has been described in detail, with reference to a specific embodiment. However, it may be obvious to anyone skilled in the art that various changes and modifications can be made within the scope and spirit of the present invention.

### INDUSTRIAL APPLICABILITY

As has been described above in detail, the present invention can provide a technique of observing a signal of a prescribed frequency in an LSI circuit, at low cost and at high precision.

1. A signal generating apparatus having an LSI circuit in which a plurality of cycle-observing signals are generated to be output via an I/O circuit to a device outside the LSI circuit in order to observe a prescribed periodic signal in the LSI circuit, the apparatus comprising:
a frequency-dividing circuit that frequency-divides the periodic signal at a preset frequency division ratio; and
a delay circuit that imparts a predetermined phase difference to the signal to be frequency-divided by the frequency-dividing circuit, thereby obtaining a plurality of signals that differ in phase from one another.

2. The signal generating apparatus according to claim 1, wherein the delay circuit imparts a prescribed phase difference to the periodic signal to be frequency-divided by the frequency-dividing circuit, before a frequency-dividing process is performed, thereby obtaining a plurality of signals that differ in phase from one another, and the frequency-dividing circuit frequency-divides the plurality of signals obtained in the delay circuit and being different in phase, each at a preset frequency division ratio.

3. The signal generating apparatus according to claim 1, wherein the delay circuit imparts a prescribed phase difference to the signal frequency-divided by the frequency-dividing circuit, thereby obtaining a plurality of signals that differ in phase from one another.

4. The signal generating apparatus according to claim 1, wherein the delay circuit imparts a phase difference to the signal to be frequency-divided by the frequency-dividing circuit, the phase difference corresponding to the time between a timing at which the periodic signal undergoes a certain waveform change and a timing at which the periodic signal undergoes the next waveform change.

5. The signal generating apparatus according to claim 1, wherein the frequency-dividing circuit frequency-divides the periodic signal at a frequency division ratio that enables the I/O circuit to transmit the periodic signal.

6. A periodic-signal observing system designed to observe a periodic signal in an LSI circuit by guiding the periodic signal out of the LSI circuit via an I/O circuit, the system comprising:
a signal generating apparatus according to any one of claims 1 to 5; and
a cycle-observing unit that observes the cycle of the periodic signal based on a phase difference between a plurality of signals generated by the signal generating apparatus and used to observe the cycle of the periodic signal.

7. An integrated circuit designed to perform a prescribed process based on a reference signal that is a periodic signal, the integrated circuit comprising:
a reference-signal generating unit that generates the reference signal in the integrated circuit;
a frequency-dividing circuit that frequency-divides the reference signal at a preset frequency division ratio;
a delay circuit that imparts a prescribed phase difference to the signal to be frequency-divided by the frequency-dividing circuit, thereby obtaining a plurality of signals that differ in phase from one another; and
an I/O circuit that guides, from the integrated circuit, a plurality of signals that have been frequency-divided by the frequency-dividing circuit and imparted with the prescribed phase difference by the delay circuit.

8. The integrated circuit according to claim 7, wherein the delay circuit imparts the prescribed phase difference to the reference signal to be frequency-divided by the frequency-dividing circuit, before a frequency-dividing process is performed, thereby obtaining a plurality of signals that differ in phase from one another, and the frequency-dividing circuit frequency-divides the plurality of signals obtained in the delay circuit and being different in phase, each at a preset frequency division ratio.

9. The integrated circuit according to claim 7, wherein the delay circuit imparts a prescribed phase difference to the signal frequency-divided by the frequency-dividing circuit, thereby obtaining a plurality of signals that differ in phase from one another.

10. The integrated circuit according to claim 7, wherein the delay circuit imparts a phase difference to the signal to be frequency-divided by the frequency-dividing circuit, the phase difference corresponding to the time between a timing at which the reference signal undergoes a certain waveform change and a timing at which the reference signal undergoes the next waveform change.

11. The integrated circuit according to claim 7, wherein the frequency-dividing circuit frequency-divides the periodic signal at a frequency division ratio that enables the I/O circuit to transmit the periodic signal.

12. A periodic-signal observing method in which a periodic signal is guided from an LSI circuit via an I/O circuit and then observed, the method comprising:
a frequency-dividing step that frequency-divides a prescribed periodic signal in the LSI circuit, at a preset frequency division ratio;
a delaying step that imparts a prescribed phase difference to the signal to be frequency-divided by the frequency-dividing circuit, thereby obtaining a plurality of signals that differ in phase from one another; and
a cycle-observing step that observes the cycle of the periodic signal based on a phase difference between a plurality of signals for cycle observation generated in the frequency-dividing step and the delaying step.

13. The periodic-signal observing method according to claim 12, wherein the delaying step imparts the prescribed phase difference to the periodic signal to be frequency-divided in the frequency-dividing step, before a frequency-dividing process is performed, thereby obtaining a plurality of signals that differ in phase from one another, and the frequency-dividing step frequency-divides the plurality of signals obtained in the delay step and being different in phase, each at a preset frequency division ratio.

14. The periodic-signal observing method according to claim 12, wherein the delaying step imparts a prescribed phase difference to the signal frequency-divided in the frequency-dividing step, thereby obtaining a plurality of signals that differ in phase from one another.

15. The periodic-signal observing method according to claim 12, wherein the delaying step imparts a phase difference to the signal to be frequency-divided in the frequency-dividing step, the phase difference corresponding to the time between a timing at which the periodic signal undergoes a certain waveform change and a timing at which the periodic signal undergoes the next waveform change.

16. The periodic-signal observing method according to claim 12, wherein the frequency-dividing step frequency-divides the periodic signal at a frequency division ratio that enables the I/O circuit to transmit the periodic signal.

17. A method of testing an integrated circuit, comprising:
a first step that frequency-divides a first periodic signal for driving the integrated circuit, at a preset frequency division ratio, and imparts a prescribed phase difference to the first periodic signal, thereby generating a second periodic signal;
a second step that frequency-divides the first periodic signal, at the preset frequency division ratio, and imparts a prescribed phase difference to the second periodic signal, thereby generating a third periodic signal;
a third step that outputs the second periodic signal and the third periodic signal from the integrated circuit; and
a fourth step that determines a phase difference between the second and third periodic signals output in the third step.
